(19) United States
(12) Patent Application Publication
(10) Pub. No.: US 2011/0303273 A1
(43) Pub. Date: Dec. 15, 2011

(54) PHOTOVOLTAIC CELL

(76) Inventor: Robert Cameron Harper, Newport (GB)

(21) Appl. No.: 13/202,403

(22) PCT Filed: Feb. 17, 2010
(86) PCT No.: PCT/GB10/00286

§ 371 Date: Aug. 19, 2011

(30) Foreign Application Priority Data
Feb. 19, 2009 (GB) 0902846.5

(51) Int. Cl. H01L 31/109; H01L 31/18; H01L 31/0312

(52) U.S. Cl. 136/255; 257/184; 438/94; 438/68; 257/E31.067; 257/E31.023

(57) ABSTRACT

There is disclosed a photovoltaic cell, such as a solar cell, incorporating one or more epitaxially grown layers of SiGe or another germanium material, substantially lattice matched to GaAs. A GaAs substrate used for growing the layers may be removed by a method which includes using a boundary between said GaAs and the germanium material as an etch stop.

### FIELD OF THE INVENTION

The present invention relates to photovoltaic cells, and in particular, but not exclusively, to multi-junction solar cells in which a lower photovoltaic junction for absorbing longer wavelength parts of the solar spectrum is germanium based.

### INTRODUCTION

Photovoltaic cells convert light energy, for example sunlight, into useful electrical power. Typically, electron-hole pairs are formed by absorption of photons in a semiconductor material close to a p-n junction which acts to separate the charge carriers which are then delivered to an electric circuit through metallic contacts on the cell device. The absorption process only occurs if a photon has an energy higher than a bandgap of the local semiconductor material, so that a lower bandgap material tends to absorb more photons. Excess energy of a particular photon over the bandgap energy is lost as heat into the semiconductor lattice. If the p-n junction is formed of materials with a higher bandgap, lower energy photons are not absorbed, but the voltage at which the photocurrent is delivered increases.

Sunlight contains significant energy over a wide range of wavelengths, and to maximise efficiency of solar cells it is therefore appropriate to absorb high energy photons in an upper junction with a higher bandgap, and absorb successively lower energy photons in underlying junctions with successively lower characteristic bandgap energies. This technique seeks to maximise the electrical power obtained from each part of the solar spectrum by absorbing higher energy photons in higher voltage junctions. It is known to form the multiple junctions monolithically on a single semiconductor substrate, using epitaxial growth techniques. The photocurrent from each junction flows through the whole structure and is coupled to an external circuit using metallic contacts on top of the upper cell and below the substrate. A solar cell formed in this way is frequently called a multijunction cell.

A well-known multi-junction cell structure is outlined in the introduction of U.S. Pat. No. 6,380,601. The upper, higher bandgap energy junction is based on InGaP materials. The middle junction is based on GaAs materials. The bottom, lower bandgap energy junction is based on Germanium materials. In particular, the lower junction is formed by suitable doping of a Ge substrate on which the middle and upper junctions are formed using epitaxial growth techniques. The materials used in each junction are constrained by the requirements of good quality epitaxial growth that the crystal lattice spacing of each layer matches the spacing of the layer below. Mismatches in lattice spacing of more than a small fraction of 1% lead to growth defects which result in poor material quality and a much lower efficiency solar cell as photo-generated charge carriers recombine more readily within the device. GaAs and Ge are closely lattice matched. The InGaP material can be lattice matched to GaAs by ensuring the correct ratio of the In, Ga and P components. Other materials which may be used in such a triple junction tandem cell must be similarly lattice matched to the substrate and each other.

In U.S. Pat. No. 6,380,601 the Germanium substrate is p-doped with gallium to a concentration of about 1×10¹⁸ cm⁻³. The bottom p-n junction is then formed by diffusion of phosphorous into a surface layer of the Ge substrate. To overcome the bulk p-type doping the diffused n-type phosphorous doping is at a relatively high concentration of about 5×10¹⁸ to 1×10¹⁹ cm⁻³, with the diffusive process leading to a gradual falling off in concentration with depth, rather than a sharp boundary.

An objective in both U.S. Pat. No. 6,380,601, and US 2002/0040727 which describes a similar device, is to improve the properties of the diffused n-type doped layer in the surface of the Ge substrate. However, using the described techniques the thickness of the n-doped layer remains difficult to control accurately, the boundary between the n- and p-doped regions is diffuse in nature, and the concentration of n-type doping must be high to counterbalance the bulk p-type doping of the substrate.

The invention addresses these and other problems of the related prior art.

### SUMMARY OF THE INVENTION

Accordingly the invention provides a photovoltaic cell, such as a solar cell, comprising a germanium based first photovoltaic junction, the junction comprising one or more epitaxially grown first layers of SiGe or another germanium material, lattice matched, or substantially lattice matched to GaAs. In particular, the one or more layers may be grown monolithically with a GaAs substrate, or another substrate providing a GaAs surface such as a GaAs-on-Insulator substrate. The junction may comprise, or be formed by, two such layers of SiGe or another germanium material, which may be oppositely doped, one or both of the layers being distinct epitaxially grown layers of said SiGe and/or Ge materials. Both layers may be lattice matched, or substantially lattice matched to GaAs. Alternatively or additionally the photovoltaic junction may be formed by adding dopants to one or more of the one or more epitaxially grown layers, or other parts such as an underlying layer or substrate, for example by diffusion or beam implant.

Although germanium alone, or SiₓGe₁₋ₓ with a silicon content of up to at least x=0.04, and perhaps x=0.06 or more, may be used in the one or more layers of germanium material, the layers are more preferably formed of suitably doped SiₓGe₁₋ₓ in which 0.01×0.03. Preferably, the first junction has a characteristic bandgap of less than 0.76 eV, and more preferably less than 0.73 eV. More generally, however, the term germanium material when used in this document may be a material in which the germanium mole fraction is at least 07, optionally at least 0.9, and the germanium material is monocrystalline and/or monolithically formed.

The one or more layers may be grown in one or more stages using an appropriate epitaxial technique such as CVD or MBE. The layers may be doped p- or n-type, to facilitate formation of the photovoltaic junction by dopant diffusion and/or growth of oppositely doped layers.

The one or more first layers may be formed of the same material composition, or the compositions may differ slightly subject to the lattice matching constraints to retain good material quality. The one or more first layers will typically be oppositely doped, but the order of the doping may be selected in line with other design constraints familiar to the skilled person. The first junction and other photovoltaic junctions which may be provided in the cell may comprise other layers or structures such as an intrinsic region between oppositely doped layers.

Compared with the techniques outlined in U.S. Pat. No. 6,380,601, and US 2002/0040727, aspects of the present invention allow the doping concentration of the upper layer of the junction to be significantly reduced, which results in improved carrier recombination lifetimes, and a consequent improvement in open circuit voltage of the junction and overall efficiency. The epitaxial growth of the one or more first layers permits much more accurate control of layer thickness and junction position, and in particular facilitates formation of a thin upper layer, with a sharp junction boundary, which cannot be achieved using diffusive counter-doping methods. Because the one or more first layers are lattice matched to the GaAs, any overlying GaAs layers such as GaAs layers in an overlying photovoltaic junction can be accurately lattice matched leading to reduced growth defects, with consequent improvements in material quality and device performance over a device in which any GaAs junction layers are only approximately lattice matched to an underlying Ge substrate.

For multi-junction solar cell applications it is generally thought desirable to provide a lower junction with a bandgap larger than that provided by germanium, and this is achieved by forming the one or more first layers from SiGe, with the Si content increasing the bandgap of the material. For a silicon content of 2% the bandgap of the junction is approximately 0.68 eV.

The processing of Ge wafers to form a diffused lower junction for solar cells tends to be restricted to maximum 100 mm wafer sizes, and the use of a GaAs wafer substrate widens access to larger wafer sizes such as 150 mm and 200 mm which are more widely available in GaAs.

Typically, the one or more first layers will have been grown epitaxially on or over a GaAs substrate, so as to provide optimal GaAs lattice matching, but in an operable device the GaAs substrate may have been removed as discussed below, for example taking advantage of the etch-stop effect of the Ge or SiGe layer when etching GaAs. To this end, the one or more first layers may be grown directly on and contacting a GaAs surface provided by the substrate. Having removed some or all of the GaAs substrate, this may be replaced by an alternative base, for example a metallic or other heatsink layer or structure, or a cheaper or more convenient substrate such as silicon, which may also have a silicon oxide layer. If a heatsink structure is used, this may be metallic or of another class of material, but should have thermal transfer characteristics better than the GaAs substrate it replaces, for example having a thermal conductivity at least double that of a GaAs substrate at usual operating conditions. Most or all of the GaAs substrate is separated by an exfoliation or layer transfer method then it may be reused in a subsequent process, for example to form other similar or different semiconductor devices.

One or more further photovoltaic junctions may be disposed over the first junction having bandgaps larger than that of the first junction. The further junctions may be epitaxially grown and monolithic with the first junction, may be grown with a different lattice constant using an intervening grade layer, and/or may include junctions separately grown for example on a different substrate and subsequently bonded to form part of the device.

For example, a silicon-germanium grade may be formed over the germanium based first photovoltaic junction and said one or more further photovoltaic junctions may then comprise at least a second photovoltaic junction formed over the silicon-germanium grade, the second junction comprising SiGe materials having a higher silicon content than the one or more first layers of the first junction, the silicon-germanium grade being formed to match the lattice constants of the first and second junctions at respective lower and upper boundaries. For typical multi-junction solar cell applications, such a second junction may typically have a bandgap of around 0.85 to 1.05 eV, although the full range from the bandgap of germanium to the bandgap of silicon is available.

To provide further photovoltaic junctions above the second junction of SiGe materials, noting that the further junctions may not be lattice matched to the second junction (for example they may comprise GaAs layers and be monolithic and lattice matched with such), an ancillary structure may be formed on a separate substrate, the ancillary structure having one or more ancillary photovoltaic junctions having bandgaps larger than the bandgaps of the germanium based first and second photovoltaic junctions. The junctions of the ancillary structure are then bonded on top of the second photovoltaic junction. Conveniently, the junctions of the ancillary structure may be created in inverse formation so that the ancillary structure can be inverted onto the main structure.

One example of a completed photovoltaic cell embodying the invention includes a monolithic triple junction solar cell comprising a first germanium based photovoltaic junction comprising epitaxially grown Ge or SiGe layers substantially lattice matched to GaAs, an epitaxially grown intermediate GaAs based photovoltaic junction, and an upper photovoltaic junction. Another example is quadruple junction solar cell comprising a first, Germanium based photovoltaic junction comprising epitaxially grown Ge or SiGe layers lattice matched to GaAs, a second photovoltaic junction comprising epitaxially grown SiGe layers having a higher silicon content than the Ge or SiGe layers of the first junction, and an intermediate SiGe grade arranged to match the lattice constant of the first and second junctions at its respective faces. Of course, different numbers of junctions and different junction materials can be used.

The invention also provides methods of forming photovoltaic cells as discussed above, for example comprising providing a GaAs substrate, or other substrate providing a GaAs surface, and forming a Germanium based first photovoltaic junction over the GaAs substrate by epitaxial growth of one or more first semiconductor layers of SiGe, Ge, or another germanium material substantially lattice matched to the GaAs substrate. Methods putting into effect the various structures discussed above are also provided.

The first of the one or more first semiconductor layers may be grown directly on the GaAs substrate, thereby providing an etch stop for a subsequent etching step which removes some or all of the GaAs substrate. Other techniques for removing some or all of the GaAs substrate may be used including grinding and layer transfer/exfoliation. Exfoliation techniques may permit re-use of the substrate in the form of a GaAs wafer of slightly reduced thickness. If the GaAs substrate is removed in whole or part, replacement structures or layers such as an alternative semiconductor substrate (for example silicon) or a metallic heatsink may be provided in its place.

### BRIEF DESCRIPTION OF THE DRAWINGS

Embodiments of the invention will now be described, by way of example only, with reference to the accompanying drawings, of which:

FIG. 1A illustrates schematically a photojunction formed using SiGe material layers epitaxially grown over a GaAs substrate;

FIG. 1B illustrates a similar photojunction, but formed using a single SiGe material layer and dopant diffusion into the substrate;

FIG. 1C illustrates a similar photojunction, but formed using a single SiGe material layer and dopant diffusion into the SiGe layer;

FIG. 2 shows the structure of FIG. 1A with additional photojunctions and other functional structures added to form a multijunction monolithic photovoltaic cell;

FIGS. 3A to 3D illustrate a process in which the structure of FIG. 2 is bonded to a handling wafer, and the GaAs substrate is removed and replaced with another base structure such as a metallic heatsink;

FIGS. 4A to 4D illustrate a process in which a structure similar to that of FIG. 1A is formed on an alternative substrate such as an oxidised silicon wafer, permitting reuse of the GaAs substrate wafer;

FIG. 5 shows a structure similar to that of FIG. 1A or FIG. 4D to which has been added a grade layer and a further photojunction formed of SiGe material layers grown epitaxially on the grade layer with a higher proportion of silicon than in the underlying photojunction;

FIG. 6A shows an ancillary photojunction structure. In FIG. 6B this structure is inverted and bonded to a structure similar that of FIG. 5. Further processing including removal of the oxidised silicon or other substrates results in the photovoltaic cell shown in FIG. 6C.

The diagrams, which generally show semiconductor layers in section through a structure, are not drawn to scale. Where p- or n-type doping are indicated, the skilled person will be aware that these can be exchanged to describe a complementary device without loss of function. In the description the terms “above”, “below”, “over”, “under” and similar terms are generally used in the sense that the discussed photovoltaic structures are intended to receive illumination for the purposes of generating a photocurrent from above, although the actual orientation of the structures, cells and devices may clearly be varied to suit particular applications.

For the sake of brevity and generality, not all layers and structures desirable or necessary to form the described photovoltaic cells are illustrated or described, and other functional and non-functional layers may be included within the described structures where the contrary is not indicated in the text.

### DESCRIPTION OF EMBODIMENTS

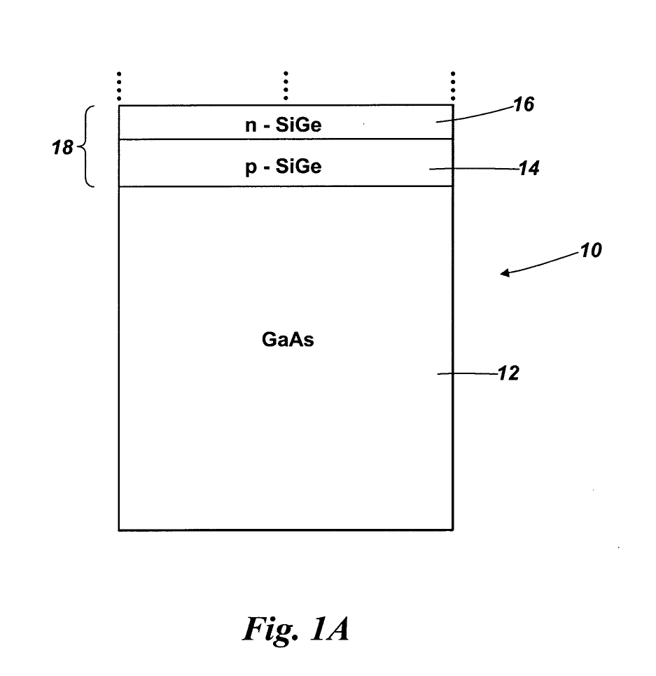

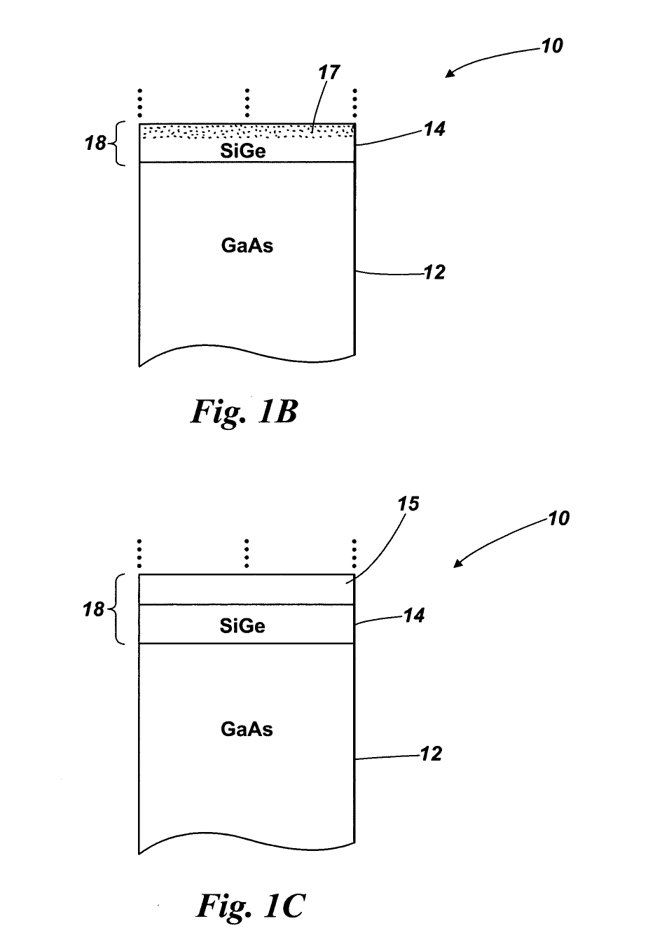

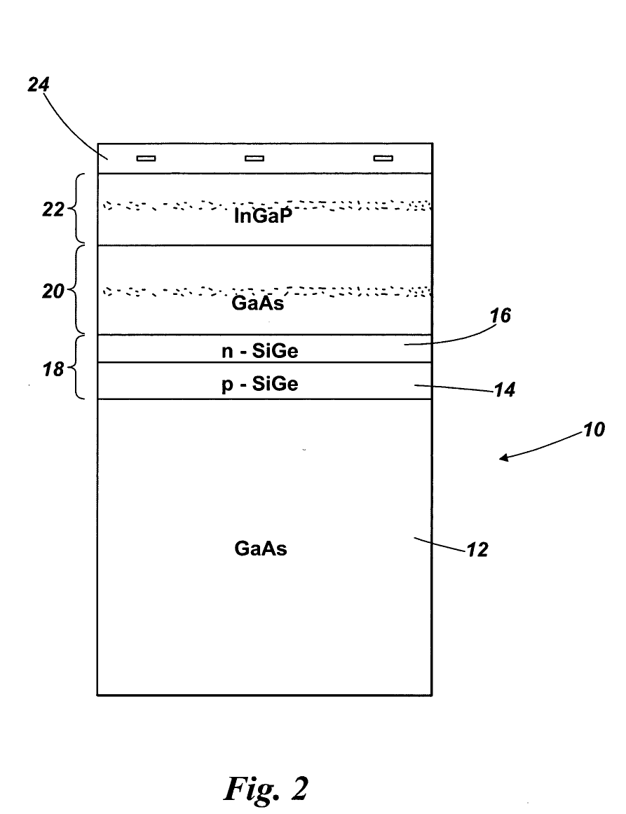

Referring to FIG. 1A there is shown schematically a photovoltaic cell structure 10 according to a first embodiment of the invention. The structure 10 comprises a GaAs substrate 12. On the GaAs substrate are two successive first layers 14, 16 of a SiGe material grown epitaxially on and monolithically with the GaAs substrate, and these layers together form a first germanium based photovoltaic junction 18. The first layers of SiGe have a silicon content selected so as to be substantially lattice matched to the GaAs substrate. To achieve this the silicon fraction x for SiₓGe₁₋ₓ could lie in the range of 0˜0.04, more preferably 0.01˜0.03 and more preferably still about 0.016˜0.02. To form a practical photovoltaic junction the lower SiGe layer may typically be p-doped to a concentration of about 5×10¹⁶ to 5×10¹⁹ cm⁻³ and have a thickness of about 1˜2 μm. The upper SiGe layer may typically be n-doped to a concentration of about 1×10¹⁷ cm⁻³ and have a thickness of about 0.2˜1 μm.

Of course, the p- and n-type dopings may be reversed as long as corresponding changes are made in other parts of the structure, as will be apparent to the skilled person. Based on a silicon fraction x for SiₓGe₁₋ₓ of zero, and 0.04, the bandgap of the junction will be about 0.67 eV and 0.69 eV respectively. The corresponding lattice mismatch of the SiₓGe₁₋ₓ with GaAs will be about 0.04% for every change of 0.01 in x away from the lattice matched condition at about x=0.018. The junction may be formed using layers in which the Si content is zero or close to zero, in which case the layers may be described as germanium layers rather than SiGe layers, although using SiGe with a closer lattice match to GaAs is advantageous. The compositions of the first layers may be identical or close to identical, or may differ subject to constraints of being substantially lattice matched so as to suppress defect formation.

The first germanium based junction and other photovoltaic junctions in the described structures may be provided by doped p- and n-layers in direct contact, or other more complex structures, for example including an intrinsic region of lightly doped or undoped material may be provided between the doped regions as will be familiar to the skilled person. Diffused or otherwise added dopants may also be used, as illustrated in FIG. 1B discussed below.

Further layers may be formed on top of the first SiGe layers as required, such as further photovoltaic junctions, tunnel junctions between such photovoltaic junctions, window layers, and conductive electrode contacts. Other layers may also be provided between the first SiGe layers and the GaAs substrate, or between the first SiGe layers such as an intrinsic region of undoped SiGe within the photovoltaic junction.

The first SiGe layers 14,16 can be grown on the GaAs substrate 12 using an epitaxy process, as lattice matched layers, using a gas mixture of a germanium containing precursor (e.g. GeH₄, GeCl₄, etc) and a silicon containing precursor (e.g. SiH₄, SiH₂Cl₂, SiHCl₃, disilane, etc) with a carrier gas (e.g. H₂). The first SiGe layers 14,16 can be in-situ doped with p-type or n-type dopants, or both, using gaseous or solid doping sources including, but not limited to, diborane, phosphine and arsine. The layers 14,16 can be grown, for example, at atmospheric pressure or reduced pressure in the range 1˜1000 Torr, and temperature 350° C.˜800° C. A range of GaAs substrates may be used including p-type, n-type and semi-insulating, and the wafers may be cleaned ex-situ or in the process chamber prior to epitaxy. Crystallinity properties of the SiGe layers 14,16 may be measured using X-ray diffraction techniques, for example to check lattice matching, and the thicknesses of the layers may typically be monitored using variable angle spectroscopic ellipsometry, although other techniques are available.

Advantages of this embodiment and the related aspects of the invention are set out in the Summary of the Invention above.

FIG. 1B illustrates a variation of FIG. 1A, in which a single layer of SiGe or another germanium material is used in the formation of a photovoltaic junction. In FIG. 1B the SiGe layer 14 carries a doping of one type throughout its structure, but is counterdoped by diffusion in an upper region 17, to form a junction within the layer 14. The junction could also be formed by other doping techniques and structures, for example of other regions of the layer, and/or of the substrate. As for FIG. 1A, further layers may optionally be added. The layer 14 may be grown as an undoped, p-type or n-type layer.

In FIG. 1C a further layer 15 of a material which is not germanium based forms part of the photovoltaic junction 18 with the germanium material layer 14.

Aspects and embodiments of the invention described below are generally illustrated using the scheme of FIG. 1A, but can equally well be implemented using schemes such as or similar to those of FIGS. 1B and 1C.

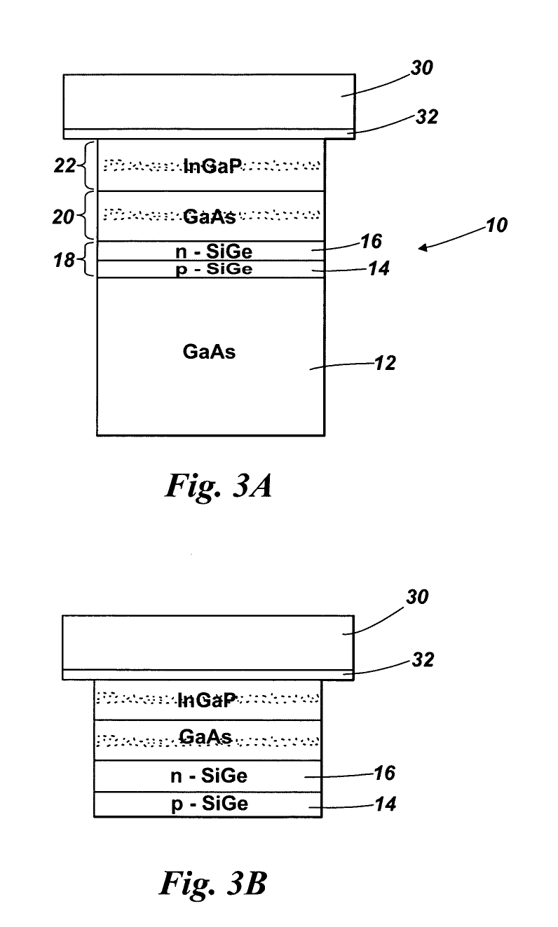

Referring to FIG. 2 there is shown schematically the photovoltaic cell structure 10 of FIG. 1A (or other similar structures), with the addition of further overlying photovoltaic junctions. These overlying junctions are typically formed epitaxially, for example using materials substantially lattice matched to GaAs. In particular, an intermediate photovoltaic junction formed of GaAs materials is shown as junction 20, and an upper photovoltaic junction formed of InGaP materials is shown as junction 22. Capping layers 24 may overlie the upper junction. Suitable tunnel junctions may be provided between the photovoltaic junctions. The intermediate junction may typically have a bandgap of around 1.4 eV. The upper junction may typically have a bandgap of around 1.85 eV. Other combinations of photovoltaic junctions of various materials and structures known in the art may be used.

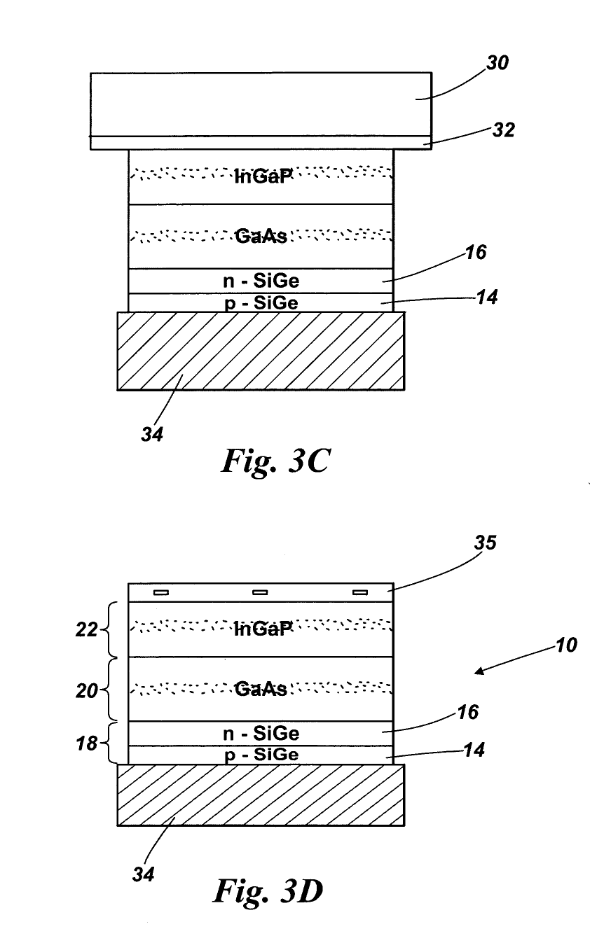

Processes involving removal of the GaAs substrate from photovoltaic cell structures such as those illustrated in FIGS. 1A, 1B, 1C and 2 will now be described. The structure of FIG. 2 will be used as an example, but it should be understood that other photovoltaic cell structures based on the structure of FIGS. 1A-1C may also be used. As shown in FIG. 3A, a handling wafer 30 is bonded to an upper surface of the structure 10. This may be before or after some or all capping layers 24 such as window and electrode layers have been added. The bonding may be achieved using a temporary bonding layer 32. The GaAs substrate is then removed, for example by grinding followed by selective wet etching, to leave a structure as illustrated in FIG. 3B. When the GaAs substrate has been removed, an alternative base 34 may be provided in substitution. FIG. 3C shows a heatsink, for example provided by a metallic layer, being provided in replacement of the GaAs substrate, although other alternative bases could be provided. Finally, as shown in FIG. 3D, the handle wafer 30 and temporary bonding layer 32 are removed. If still required, further layers 35 may then be added to the top of the device structure.

In this process, the change of material composition between the GaAs substrate and the one or more first SiGe layers 14,16 provides a hetero-interface which acts as a good etch-stop, enabling the GaAs substrate to be removed conveniently and accurately to leave a smooth surface of the lower SiGe layer 14. Some of the GaAs substrate may be removed by mechanical means if this provides more rapid or otherwise convenient or cost-effective manufacture process. For example, if the GaAs substrate is 500 μm thick, about 400 μm may be removed by grinding from which the GaAs material can be more easily recovered and re-used, and the final 100 μm may be removed by selective wet etching.

The photovoltaic cell structure resulting from use of this method, as shown in FIG. 3D, can be of lighter weight because the substrate thickness has been removed, which may be important particularly in space-based applications. An alternative base which has favourable flexibility, thermal behaviour, or other desirable mechanical or electrical properties may be advantageously provided. Replacement of the substrate with a heatsink can result in more efficient thermal conduction away from the device because the substrate no longer acts to reduce the flow of heat. The heatsink or another metallic base layer can act directly as a conductive electrode to the bottom of the device.

This process cannot be carried out in a device constructed with the prior art techniques outlined in U.S. Pat. No. 6,380,601, and US 2002/0040727, because these techniques do not provide a suitable hetero-interface to act as an etch-stop between the substrate and the lower junction 18.

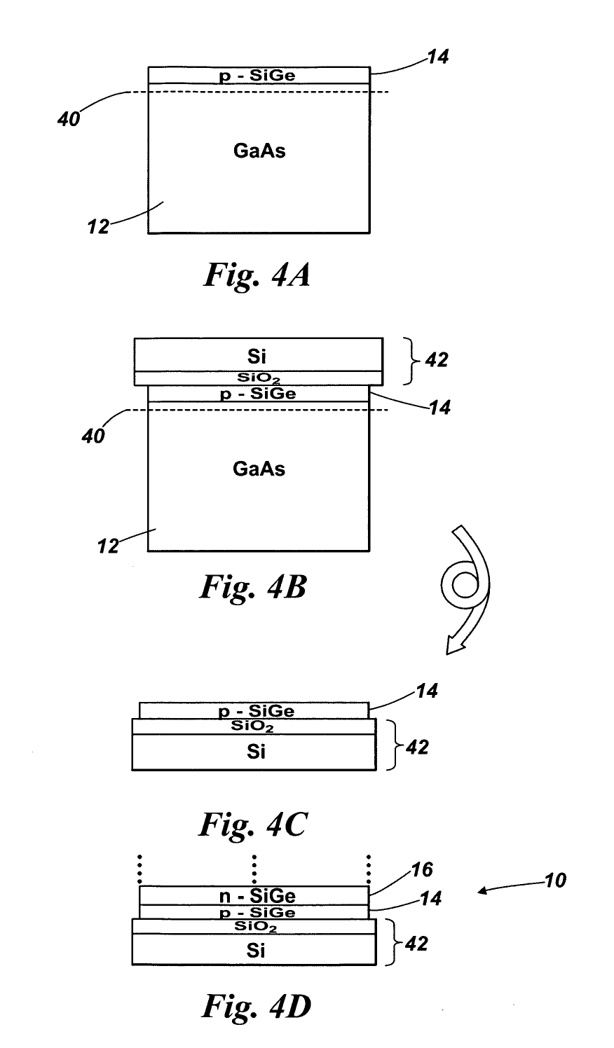

Another technique for providing an alternative base for the structures of FIGS. 1A-1C is illustrated in FIGS. 4A-4E. Starting with a GaAs substrate, a lower layer 14 of SiGe is grown epitaxially as previously described, and as shown in FIG. 4A. A layer transfer technique is then used to remove all but a thin layer of the GaAs substrate. The layer transfer may be achieved using a proprietary exfoliation technique such as Smart Cut® or similar, in which a cleave plane 40 is formed in the GaAs substrate just beneath the first layer 14 of SiGe. The cleave plane 40 may be formed using ion beam implant techniques to deposit hydrogen or helium atoms at a precise depth determined by the beam particle energy, for example at depths of up to about 1.5 μm, making the technique practical in the present context if the thickness of the lower layer of SiGe is of approximately this thickness. The technique may also be used following growth of both the first layers of SiGe (in inverse order), if the combined thickness of the two layers is not too great for the layer transfer technique to be used effectively or conveniently.

An alternative base is then bonded to the SiGe layer 14. As shown in FIG. 4B the alternative base may be an oxidised silicon wafer 42 such that the SiGe layer is bonded to a layer of SiO₂, although other bases may be used such as the metallic heat sink layer discussed above. Some other bases which can be used are metallic, glass and semiconductor bases, which may themselves already comprise two or more layers selected from metal, semiconductor and insulator materials, and may include active elements such as one or more photovoltaic junctions. The bulk of the GaAs substrate is then separated from the structure, and the fine remaining layer of GaAs is removed, for example by selective wet etching, to leave the first layer 14 of SiGe on an alternative base such as the oxidised silicon wafer discussed, and as shown in FIG. 4C.

Another first layer 16 of SiGe (if not already present) and subsequent photovoltaic device structures may then be formed as shown in FIG. 4D, for example as discussed elsewhere in this document and as already illustrated in FIGS. 1A and 2.

One variation of the described technique is to form the cleave plane just above the interface with the substrate, within the lower SiGe layer. Following layer transfer the transferred SiGe is already exposed for any necessary further preparation. The residual SiGe remaining on the GaAs substrate can be removed, at least partially using a net etch selective for SiGe and ineffective on GaAs, to leave a reuseable GaAs substrate wafer.

This and other layer transfer techniques which can be used to set out in detail in the commonly filed and copending patent application entitled “Formation of thin layers of GaAs and germanium materials”, which is hereby incorporated by reference in its entirety for all purposes.

A wide variety of different alternative bases may be contemplated for the structure of FIG. 4D, including metallic, glass, and semiconductor bases, which may themselves already comprise two or more layers selected from metal, semiconductor, and insulator materials, and may include active elements such as one or more photovoltaic junctions. The initial formation of one or more SiGe layers on a GaAs substrate provides an ideal etchstop for accurate removal of the remaining GaAs following cleaving or exfoliation.

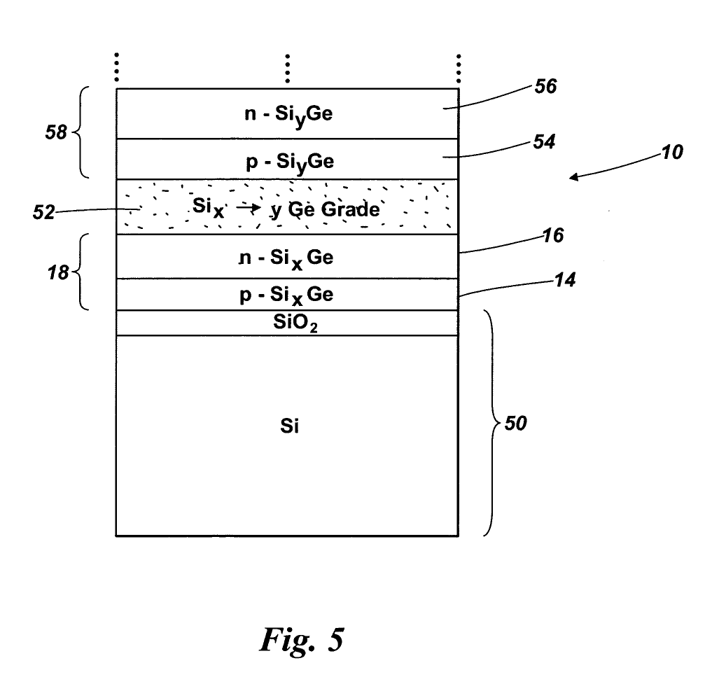

Starting with the structure of FIG. 1A or FIG. 4D, an alternative scheme for constructing further layers is shown in FIG. 5. FIG. 5 shows a base layer 50 of silicon oxide on a silicon substrate, but other base layers including the original GaAs substrate may be used. Following formation of the two first SiGe layers 14,16 discussed in connection with FIG. 1A, a grade layer 52 has been grown on the upper first SiGe layer 16. The grade layer 52 is also formed of SiGe and provides a transition in lattice spacing between the SiGe of the upper first SiGe layer 16, in which the Si fraction is denoted x, and a further, overlying lower second SiGe layer 54 in which the Si fraction is denoted y, where y>x. An upper second SiGe layer 56 with a similar or identical Si fraction y is grown above the lower second layer, to thereby form a second SiGe photovoltaic junction 58. Because the SiGe material of the second photovoltaic junction 58 has a higher silicon content than the first junction 18, the bandgap of this second SiGe junction is higher, and moreover is tunable by adjusting the value of y during manufacture from close to the bandgap of Ge at about 0.67 eV for a material with little or no Si content, to close to the bandgap of Si at about 1.12 eV, for a material with little or no Ge content. A suitable bandgap range which may be desirable in a multi-junction solar cell is about 0.85 eV to about 1.05 eV. The SiGe grade layer permits the second SiGe layers to be strain relaxed with a low density of threading dislocations, and as illustrated in FIGS. 1B and 1C for the first layer, just one second layer may be used.

The one or more second SiGe layers can be grown using techniques and parameters similar to those discussed above in respect of the first layers. Further layers including further junction layers may be added to the structure, either by using materials lattice matched to the second layers, or by other techniques as outlined below.

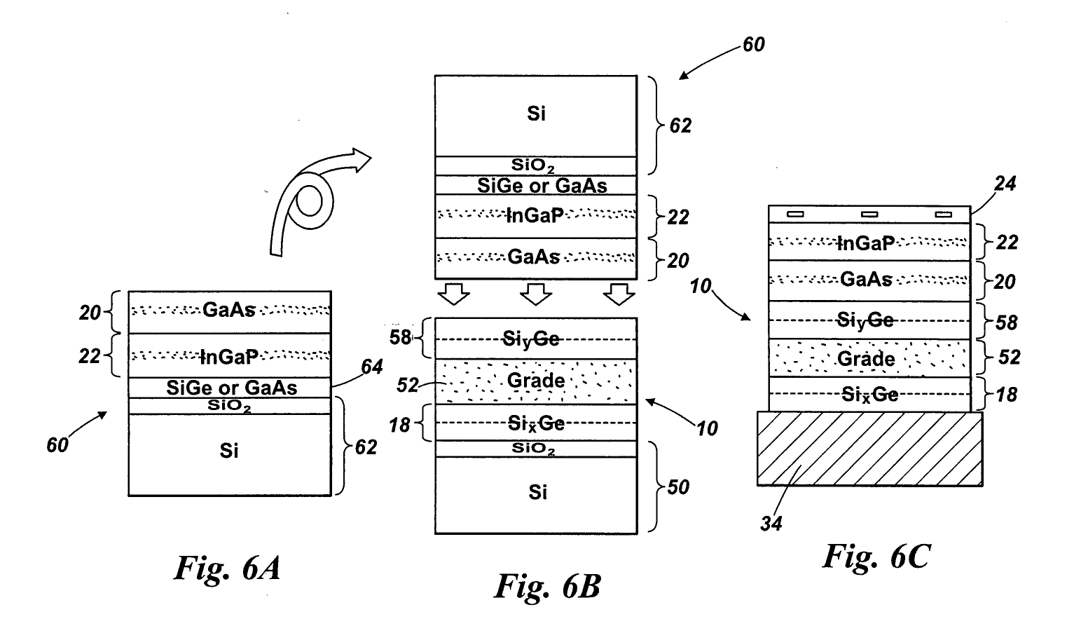

The SiGe grade 52 has the effect that the second SiGe junction 58 is formed of material which is not lattice matched to GaAs. To provide one or more further photovoltaic junctions which are lattice matched to GaAs, on top of the structure of FIG. 5, an ancillary structure 60 as shown in FIG. 6A is formed. This structure is based on an ancillary substrate 62. The photovoltaic junctions required for adding above the second SiGe junction 58 are then formed on the ancillary substrate 62 in inverted order. The ancillary structure 60 is then inverted and bonded to the second SiGe junction 58 as shown in FIG. 6B, to provide the required photovoltaic cell structure sandwiched between the ancillary substrate 62 above and the base layer 50 below. The base layer 50 may then be removed if desired, for example for replacement by a heat sink, or other base structure as listed in previous examples. The ancillary substrate 62 is removed to expose the top of the photovoltaic cell structure, and further layers such as any window and electrode layers not already provided, may be added, thereby providing a quadruple tandem photovoltaic cell structure as illustrated in FIG. 6C.

The ancillary structure shown in FIG. 6A includes an ancillary substrate 62 formed of an oxidised silicon wafer, on which a thin lattice matching layer 64, for example formed of SiGe or GaAs is provided, for example by layer transfer/exfoliation as already described above in connection with FIGS. 4A and 4B. Because this lattice matching layer is of well formed GaAs, or SiGe lattice matched to GaAs, further structures incorporating GaAs may be grown with good material quality. In the example of FIG. 6A an upper photovoltaic junction 22 based on GaInP materials is then formed above the lattice matching layer 64, and an intermediate photovoltaic junction 20 formed of GaAs materials is formed above the upper junction 22. Suitable materials, structures, and other variations for these junctions have already been discussed above with respect to FIG. 2. Noting that the upper junction may have a bandgap of around 1.85 eV, the intermediate junction may have a bandgap of around 1.4 eV, and the first SiGe junction may have a bandgap of around 0.7 eV, a suitable bandgap for the second SiGe junction may be about 0.95 eV, although using the described construction and techniques, this can be tuned as desired to optimise the efficiency of the photovoltaic cell, for example to different light spectra and intensities. Tunnel junctions and other elements may be provided for ensuring appropriate current flow between various parts of the device.

### Variations

It will be apparent that a range of modifications and variations may be made in respect of the described embodiments without departing from the invention. The methods and structures may be used for a variety of applications including solar cell applications, thermovoltaic applications, as well as photodetector and other electronics applications.

The invention may be put into effect using a variety of fabrication techniques to form required monolithic structures.

Alternative base structures for the various aspects described may include semiconductors, metals, ceramics, glasses, and combinations of such materials. Alternative bases may include active elements such as photovoltaic junctions including thermovoltaic junctions, and elements ancillary to such junctions. Alternative base structures may be used as heatsinks to provide improved thermal transfer (for example compared with the original substrate) and other desired functionality.

1. A photovoltaic cell comprising a first photovoltaic junction, the junction comprising one or more first semiconductor layers,
the one or more first semiconductor layers being epitaxially grown layers of SiGe and/or other germanium material substantially lattice matched to GaAs.

2. The cell of claim 1 wherein the one or more first layers are formed of suitably doped SiₓGe₁₋ₓ in which 0.01≦x≦0.3.

3. The cell of claim 1 wherein the germanium material of the one or more first layers has a germanium mole fraction of at least 0.7.

4. The cell of claim 1, 2 or 3 wherein the first junction has a characteristic bandgap of less than 0.76 eV.

5. The cell of any preceding claim wherein the junction is formed using two of said semiconductor layers.

6. The cell of claim 5 wherein the two layers are oppositely doped.

7. The cell of any of claims 1 to 6, wherein the one or more first semiconductor layers are layers which have been epitaxially grown on, and monolithically with, a GaAs substrate, or other substrate providing a GaAs surface.

8. The cell of claim 7, wherein the cell comprises said substrate on which the first semiconductor layers have been grown.

9. The cell of claim 7, wherein the cell does not comprise said substrate, which has been removed using a boundary between said GaAs substrate and said germanium material as an etch stop.

10. The cell of any of claims 7 to 9 wherein the one or more first semiconductor layers have been grown directly on the GaAs surface of said substrate.

11. The cell of any preceding claim wherein the cell does not comprise a GaAs substrate.

12. The cell of claim 11 comprising a heatsink structure bonded beneath the first junction without an intermediary semiconductor substrate therebetween.

13. The cell of claim 11 comprising a silicon substrate.

14. The cell of claim 13 wherein the silicon substrate comprises a layer of silicon oxide on the side of the substrate facing the first junction.

15. The cell of any preceding claim further comprising one or more further photovoltaic junctions disposed over the first junction having bandgaps larger than that of the first junction

16. The cell of claim 15 wherein a silicon-germanium grade is formed over the germanium based first photovoltaic junction and said one or more further photovoltaic junctions comprises a second photovoltaic junction formed over the silicon-germanium grade, the second junction comprising one or more second layers being epitaxially grown layers of SiGe materials having a higher silicon content than the one or more first layers, the silicon-germanium grade being formed to match the lattice constants of the first and second junctions at respective lower and upper boundaries.

17. The cell of claim 16 wherein the second photovoltaic junction has a bandgap of between 0.85 eV and 1.05 eV.

18. The cell of claim 16 or 17 further comprising a monolithically formed ancillary structure of one or more ancillary photovoltaic junctions having bandgaps larger than the bandgaps of the germanium based first and second photovoltaic junctions, the ancillary structure overlying and being lattice mismatched with the second photovoltaic junction.

19. The cell of claim 18 in which the ancillary structure is lattice matched to GaAs.

20. The cell of claim 19 wherein one of the ancillary junctions is a GaAs photovoltaic junction, and another of the ancillary junctions is an InGaP photovoltaic junction.

21. The cell of claim 15 wherein the one or more further photovoltaic junctions comprises a photovoltaic junction of GaAs materials formed monolithically with the germanium based first photovoltaic junction.

22. The cell of claim 21 wherein the one or more further photovoltaic junctions comprises a photovoltaic junction of InGaP materials formed monolithically with the GaAs junction.

23. A monolithic triple junction solar cell comprising a first germanium based photovoltaic junction comprising epitaxially grown Ge or SiGe layers substantially lattice matched to GaAs, an epitaxially grown intermediate GaAs based photovoltaic junction, and an upper photovoltaic junction.

24. A quadruple junction solar cell comprising a first Germanium based photovoltaic junction comprising epitaxially grown Ge or SiGe layers lattice matched to GaAs, a second photovoltaic junction comprising epitaxially grown SiGe layers having a higher silicon content than the Ge or SiGe layers of the first junction, and a SiGe grade arranged to match the lattice constant of the first and second junctions at its respective faces.

25. A method of forming a photovoltaic cell comprising:
providing a GaAs substrate;
forming a Germanium based first photovoltaic junction over the GaAs substrate, the junction comprising one or more first epitaxially grown semiconductor layers of SiGe, Ge, and/or other germanium material substantially lattice matched to the GaAs substrate.

26. The method of claim 25 wherein the one or more first layers are formed of oppositely doped SiₓGe₁₋ₓ in which x<0.04, and more preferably 0.01≦x≦0.03.

27. The method of claim 25 wherein the germanium materials have a germanium mole fraction of at least 0.7.

28. The method of claim 25, 26 or 27 wherein the first junction is formed so as to have a characteristic bandgap of less than 0.76 eV.

29. The method of any of claims 25 to 28 wherein the first semiconductor layer is grown directly on the GaAs substrate.

30. The method of any of claims 25 to 29 further comprising forming one or more further photovoltaic junctions over the first junction such that during operation a common photocurrent flows through the first and further photovoltaic junctions.

31. The method of any of claims 25 to 30 further comprising removing some or all of the GaAs substrate.

32. The method of claim 31 wherein the step of removing comprises removing at least some of the GaAs substrate mechanically.

33. The method of claim 32 wherein the step of removing at least some of the GaAs substrate mechanically comprises a step of forming a cleave plane in the GaAs substrate by ion implantation.

34. The method of claim 33 wherein the step of forming a cleave plane is carried out after growth of a first one of said one or more first layers, and before growth of a second one or said one or more first layers.

35. The method of any of claims 32 to 34 wherein the step of removing at least some of the GaAs substrate mechanically comprises grinding the GaAs substrate.

36. The method of any of claims 31 to 35 wherein removing the GaAs substrate comprises etching at least a remaining portion of said substrate.

37. The method of any of claims 31 to 36 further comprising replacing the GaAs substrate, in part or whole, with an alternative base.

38. The method of claim 37 wherein the alternative base comprises a heatsink.

39. The method of claim 37 wherein the alternative base comprises a silicon wafer.

40. The method of any of claims 31 to 39 wherein at least some of the removed GaAs substrate is reused as a GaAs substrate wafer in a method of formation of another semiconductor device such as another photovoltaic cell.

41. The method of any of claims 30 to 40 wherein said one or more further photovoltaic junctions comprises a second photovoltaic junction comprising one or more second epitaxially grown layers of SiGe materials having a higher silicon content than the first layers, the method further comprising forming a silicon-germanium grade over the germanium based first photovoltaic junction before growth of the second photovoltaic junction, the silicon-germanium grade being formed to match the lattice constants of the first and second junctions at respective lower and upper boundaries.

42. The method of claim 41 wherein the second photovoltaic junction has a bandgap of between 0.85 eV and 1.05.

43. The method of claim 41 or 42 further comprising forming an ancillary structure of one or more epitaxially grown ancillary photovoltaic junctions having bandgaps larger than the bandgaps of the first and second photovoltaic junctions and being lattice mismatched with the second photovoltaic junction, and bonding the ancillary structure on top of the second photovoltaic junction such that in operation a common photocurrent passes through the first, second and ancillary junctions.

44. The method of claim 43 wherein said ancillary structure is formed on an ancillary substrate and the ancillary substrate is removed after the step of bonding.

45. The method of claim 43 or 44 in which the ancillary structure is lattice matched to GaAs.

46. The method of any of claims 43 to 45 wherein one of the ancillary junctions is a photovoltaic junction of GaAs materials, and another of the ancillary junctions is a photovoltaic junction of InGaP materials.

47. The method of any of claims 30 to 40 wherein the one or more further photovoltaic junctions comprises a GaAs photovoltaic junction formed monolithically with the germanium based first photovoltaic junction.

48. The method of claim 47 wherein the one or more further photovoltaic junctions comprises an InGaP photovoltaic junction formed monolithically with the GaAs junction.

49. A method of forming photovoltaic cell comprising a photovoltaic junction comprising one or more layers of a germanium material, comprising: growing said one or more layers on a GaAs substrate; and removing said GaAs substrate using said germanium material as an etch stop.

50. The method of claim 49 wherein said step of removing comprises mechanically separating the GaAs substrate from the germanium material by exfoliation.

51. The method of claim 50 further comprising reusing the separated GaAs substrate as a GaAs wafer in production of further semiconductor devices.

52. The method of any of claims 49-51 wherein the germanium material is SiGe.

53. The method of any of claims 49-52 wherein the one or more layers are grown epitaxially.

54. The method of claim 53 wherein the one or more layers are grown directly on a surface of said GaAs substrate.

55. A photovoltaic cell formed using a method comprising the steps of any of claims 25 to 54.
